(19) United States
(12) Patent Application Publication
(10) Pub. No.: US 2024/0141230 A1
(43) Pub. Date: May 2, 2024

(54) QUANTUM DOT MANUFACTURING METHOD AND QUANTUM DOT

(71) Applicant: NS MATERIALS INC., Fukuoka (JP)

(72) Inventors: Mikihiro TAKASAKI, Fukuoka (JP); Yuka TAKAMIZUMA, Fukuoka (JP); Hironori MATSUZAWA, Fukuoka (JP)

(73) Assignee: NS MATERIALS INC., Fukuoka (JP)

(21) Appl. No.: 18/278,261

(22) PCT Filed: Feb. 25, 2022
(86) PCT No.: PCT/JP2022/007812

§ 371 Date: Aug. 22, 2023

(30) Foreign Application Priority Data
Feb. 26, 2021 (JP) 2021-030560

(51) Int. Cl. C09K 11/88

(52) U.S. Cl. CPC C09K 11/883

(57) ABSTRACT

An object of the present invention is to provide a quantum dot and a method for manufacturing a quantum dot capable of enhancing the EQE. A method for manufacturing the quantum dot of the present invention includes steps of: generating a core and coating a shell on a surface of the core, wherein in the step of coating the shell, an acidic compound and a zinc halide compound are blended in a shell raw material. In the present invention, the step of coating the shell is divided into at least a first half and a second half. In the first half, a shell raw material in which the acidic compound is blended and the zinc halide compound is not blended is used, while in the second half, it is preferable that the shell is coated a plurality of times using the shell raw material in which both the acidic compound and the zinc halide compound are blended.

### TECHNICAL FIELD

The present invention relates to a quantum dot, and a method for manufacturing a quantum dot having a core-shell structure not containing cadmium.

### BACKGROUND ART

The quantum dot emits fluorescence, and is also called a fluorescent nanoparticle because its size is a nano-order size, a semiconductor nanoparticle because its composition is derived from a semiconductor material, or a nanocrystal because its structure has a specific crystal structure.

Examples of quantum dot performance include a fluorescence quantum yield (QY) and an external quantum efficiency (EQE).

When photoluminescence (PL) is adopted as a light emission principle as an application of a display using a quantum dot, a method is adopted of using a blue LED as a backlight to generate excitation light and converting the excitation light into green light or red light using a quantum dot. On the other hand, for example, when electroluminescence (EL) is adopted as the light emission principle or when all three primary colors are caused to emit a quantum dot by another method, a blue fluorescent quantum dot is required.

Representative examples of a blue quantum dot include a cadmium selenide (CdSe) based quantum dot using cadmium (Cd). However, Cd is internationally regulated, and there is a high barrier for practical use of materials using the quantum dot of CdSe.

On the other hand, development of quantum dot not using Cd has also been studied. For example, development of a chalcopyrite-based quantum dot such as CuInS₂ and AgInS₂, an indium phosphide (InP) based quantum dot, and the like has been undergoing (see, for example, Patent Literature 1). However, quantum dots currently developed generally have a wide fluorescence half-value width and are not suitable as the blue fluorescent quantum dot.

In addition, Non Patent Literature 1 below describes in detail a direct synthesis method of ZnSe using diphenylphosphine selenide that is considered to have a relatively high reactivity with an organozinc compound, but is not suitable as the blue fluorescent quantum dot.

In addition, the following Non Patent Literature 2 also reports a method for synthesizing ZnSe in an aqueous system. Although the reaction proceeds at a low temperature, a fluorescence half-value width is 30 nm or more and slightly wide, and a fluorescence wavelength is less than 430 nm, and thus it is not suitable to use this as a substitute for a conventional blue LED to achieve a high color gamut.

Also, Non Patent Literature 3 below reports a method for synthesizing ZnSe-based quantum dots by forming a precursor such as copper selenide (CuSe) and then cation-exchanging copper with zinc (Zn). However, since particles of copper selenide as a precursor are as large as 15 nm and reaction conditions during cation exchange between copper and zinc are not optimal, it is found that copper remains in the ZnSe-based quantum dots after the cation exchange. From study results of the present invention, it has been found that the ZnSe-based quantum dots in which copper remains cannot emit light. Alternatively, in a case where copper remains even when light is emitted, the light is emitted from a defect, and the half-value width of emission spectrum is 30 nm or more. This copper remaining is also affected by a particle size of copper selenide as a precursor, and in a case where the particles are large, copper tends to remain even after the cation exchange, and even when ZnSe can be confirmed by XRD, light is not emitted due to slight copper residue in many cases. Accordingly, Non Patent Literature 3 is an example in which copper remains because a particle size control of the precursor and optimization of a cation exchange method cannot be performed. Therefore, blue fluorescence has not been reported. As described above, there are many reports based on the cation exchange method, but there is no report about strongly emitting light for the reasons described above.

### CITATION LIST

### Patent Literature

Patent Literature 1: WO 2007/060889 A

### Non Patent Literature

Non Patent Literature 1: Organic Electronics 15 (2014) 126-131
Non Patent Literature 2: Materials Science and Engineering C 64 (2016) 167-172
Non Patent Literature 3: J. Am. Chem. Soc. (2015)137 29 9315-9323

### SUMMARY OF INVENTION

### Technical Problem

Here, the external quantum efficiency is calculated by the following (Formula 1).

External quantum yield (EQE)=carrier balance×generation efficiency of emissive excitons×emission quantum efficiency (fluorescence quantum yield (QY))×light extraction efficiency (Formula 1)

Here, since the light extraction efficiency is generally 0.2 to 0.3, when the carrier balance, the generation efficiency of emissive excitons, and the fluorescence quantum yield are all 1 (100%), a theoretical external quantum yield is 20 to 30%. Accordingly, in order to obtain a high EQE, quantum dots having a high QY are required.

In addition, when a distance between the quantum dots is too short, a Förster resonance energy transfer (FRET) occurs. As a result, the EQE decreases. Thereupon, by adopting the core-shell structure in which the shell is covered around the core, the distance between the cores can be physically separated, and the FRET can be reduced.

However, in conventional art, a quantum dot capable of covering the shell having a substantially uniform thickness over an entire circumference of the core and having a high QY have not been manufactured at a level that is possible for mass production. For example, it has been found that when a shell thickness is increased, a particle shape is deteriorated, and the QY is also decreased accordingly.

Thereupon, the present invention has been made in view of the above points, and an object of the present invention is to provide a quantum dot and a method for manufacturing a quantum dot capable of increasing the EQE.

### Solution to Problem

The method for manufacturing a quantum dot of the present invention includes a step of generating a core, and a step of coating a surface of the core with a shell, and in the step of coating the shell, an acidic compound and a zinc halide compound are blended in a shell raw material.

In the present invention, the surface of the core containing at least Zn and Se is preferably coated with ZnS.

In the present invention, the step of coating the shell is divided into at least a first half and a second half. In the first half, a shell raw material in which the acidic compound is blended and the zinc halide compound is not blended is used, while in the second half, it is preferable that the shell is coated a plurality of times using the shell raw material in which both the acidic compound and the zinc halide compound are blended.

In the present invention, it is preferable to use at least one of hydrogen chloride, hydrogen bromide, or trifluoroacetic acid as the acidic compound.

In the present invention, it is preferable to use at least one of zinc chloride and zinc bromide as the zinc halide compound.

In the present invention, the core is preferably made of ZnSe or ZnSeTe.

The quantum dot of the present invention is a quantum dot including a core and a shell covering the surface of the core, wherein the quantum dot contains a halogen element and has an external quantum efficiency of 7% or more.

The quantum dot of the present invention is a quantum dot including a core and a shell covering the surface of the core, wherein the quantum dot contains a halogen element and has a fluorescence quantum yield of 70% or more.

The quantum dot of the present invention is a quantum dot having the core and the shell covering the surface of the core, wherein the shell is formed by blending the acidic compound and the zinc halide compound in the shell raw material.

In the present invention, it is preferable that the core contains at least Zn and Se and the shell is made of ZnS.

### Advantageous Effects of Invention

According to the method for manufacturing the quantum dot of the present invention, a quantum dot having a good particle shape can be synthesized, QY can be improved, and eventually, the high EQE can be obtained.

### BRIEF DESCRIPTION OF DRAWINGS

FIGS. 1A and 1B are schematic diagrams of quantum dots in an embodiment of the present invention.

FIG. 2 is a schematic diagram of an LED device using quantum dots according to the embodiment of the present invention.

FIG. 3 is a longitudinal sectional view of a display device using the LED device according to the embodiment of the present invention.

FIG. 4 is a flowchart for explaining a quantum dot manufacturing process according to the embodiment of the present invention.

FIG. 5 is a photoluminescence (PL) spectrum of Example 1.

FIG. 6 is an absorption spectrum of Example 1.

FIG. 7 is an X-ray diffraction spectrum (XRD spectrum) of Example 1.

FIG. 8 is a table showing measurement results of quantum dots of Examples 1 to 7.

FIG. 9A is a photograph of an analysis result of TEM-EDX in Comparative Example 1, and FIG. 9B is a photograph of an analysis result of TEM-EDX in Example 1.

FIG. 10A is a partial schematic view of FIG. 9A, and FIG. 10B is a partial schematic view of FIG. 9B.

### DESCRIPTION OF EMBODIMENTS

Hereinafter, one embodiment of the present invention (hereinafter, it is abbreviated as “embodiment”) will be described in detail. Note that the present invention is not limited to the following embodiments, and various modifications can be made within the scope of the gist of the present invention.

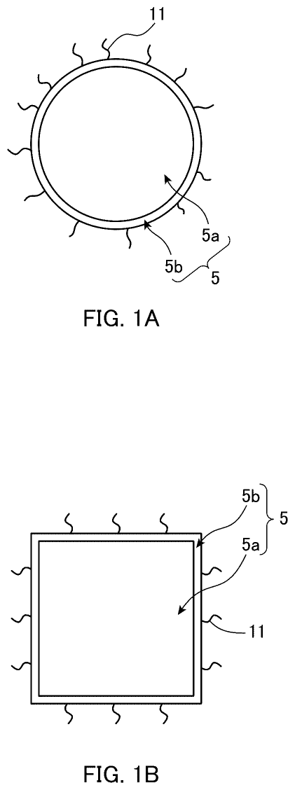

FIGS. 1A and 1B are the schematic diagrams of quantum dots in the present embodiment. The quantum dots 5 shown in FIGS. 1A and 1B are nanocrystals containing no cadmium (Cd). The term “nanocrystal” refers to nanoparticles having a particle size of about several nm to several tens of nm. In the present embodiment, a large number of quantum dots 5 can be generated with a substantially uniform particle size.

In the present embodiment, each of the quantum dots 5 has the core-shell structure of a core 5a and a shell 5b covering the surface of the core 5a. The core 5a is preferably a nanocrystal containing at least zinc (Zn) and selenium (Se). In addition, the core 5a can also contain tellurium (Te) or sulfur (S). However, it is preferable that the core 5a does not contain cadmium (Cd) or indium (In).

In addition, similarly to the core 5a, the shell 5b coated on the surface of the core 5a preferably does not contain cadmium (Cd) or indium (In). In the present embodiment, the shell 5b contains a large amount of zinc (Zn). Specifically, the shell 5b is preferably made of zinc sulfide (ZnS), zinc selenide (ZnSe), or zinc selenide sulfide (ZnSeS). Among them, ZnS is preferable. Note that the shell 5b may be in a state of being solid-solved on the surface of the core 5a. In the present embodiment, by adopting the core-shell structure, a further increase in the fluorescence quantum yield (QY) can be expected while the fluorescence half-value width is narrow.

The quantum dots 5 of the present embodiment can cover an entire surface of the core 5a with the shell 5b such as ZnS in a predetermined thickness. In addition, an intermediate layer may be interposed between the core 5a and the shell 5b. For example, this intermediate layer is the first layer of the shell, that is, the shell 5b may have a structure of two or more layers. As an example, the shell 5b having a stacked structure of ZnSeS/ZnS can be presented.

The quantum dots 5 may have a cross section that is circular as illustrated in FIG. 1A or that is polygonal as illustrated in FIG. 1B. In the case of the polygonal shape, for example, a substantially rectangular shape or a substantially triangular shape is preferable. In the present embodiment, the core 5a of the quantum dots 5 preferably contains at least Zn and Se, but as a result, the core 5a constituting the quantum dots 5 is easily formed into a polyhedron (for example, a substantially cubic shape) by crystal growth. In other words, in the present embodiment, the quantum dots 5 can be formed in an excellent shape in which the particle shapes are uniform rather than being amorphous. In the present embodiment, the shell 5b can be formed with a substantially constant thickness over the entire circumference of the core 5a. Although not limited, the shell 5b can be formed to have a thickness of about 0.5 mm to 3 mm, preferably 1 mm or more and 2.5 mm or less. This is because the acidic compound is blended in the shell raw material as described in the manufacturing method to be described later. In addition, in the present embodiment, the shell raw material is blended with a zinc halide compound, and as a result, QY can be improved.

As shown in FIGS. 1A and 1B, a large number of organic ligands 11 are preferably coordinated to the surface of the quantum dots 5. As a result, aggregation of the quantum dots 5 can be suppressed, and desired optical characteristics are exhibited. Furthermore, by adding an amine or thiol-based ligand, stability of quantum dot light emission characteristics can be greatly improved. The ligand that can be used in the reaction is not particularly limited, and representative examples thereof include the following ligands.

(1) Aliphatic Primary Amine Based

Oleylamine: C₁₈H₃₅NH₂, stearyl (octadecyl) amine: C₁₈H₃₇NH₂, dodecyl (lauryl) amine: C₁₂H₂₅NH₂, decylamine: C₁₀H₂₁NH₂, octylamine: C₈H₁₇NH₂

(2) Fatty Acid Based

Oleic acid: C₁₇H₃₃COOH, stearic acid: C₁₇H₃₅COOH, palmitic acid: C₁₅H₃₁COOH, myristic acid: C₁₃H₂₇COOH, lauric acid: C₁₁H₂₃COOH, decanoic acid: C₉H₁₉COOH, octanoic acid: C₇H₁₅COOH

(3) Thiol Based

Octadecanethiol: C₁₈H₃₇SH, hexadecanethiol: C₁₆H₃₃SH, tetradecanethiol: C₁₄H₂₉SH, dodecanethiol: C₁₂H₂₅SH, decanethiol: C₁₀H₂₁SH, octanethiol: C₈H₁₇SH

(4) Phosphine Based

Trioctylphosphine: (C₈H₁₇)₃P, triphenylphosphine: (C₆H₅)₃P, tributylphosphine: (C₄H₉)₃P

(5) Phosphine Oxide Based

Trioctylphosphine oxide: (C₈H₁₇)₃P═O, triphenylphosphine oxide: (C₆H₅)₃P═O, tributylphosphine oxide: (C₄H₉)₃P═O

(6) Alcohol Based

Oleyl alcohol: C₁₈H₃₆O

In addition, it is preferable that an inorganic ligand is coordinated together with an organic ligand. As a result, quantum dot surface defects can be further suppressed, and better optical characteristics can be exhibited. The ligand is not particularly limited, but a halogen such as F, Cl, Br, or I is a typical example.

In the quantum dots 5 in the present embodiment, as a result of elemental analysis by energy dispersive X-ray spectroscopy (EDX), a halogen element is also detected in addition to Zn, Se, and S. The halogen element is preferably chlorine (Cl) or bromine (Br).

Content of the halogen element is not limited, but is sufficiently smaller than Zn, Se, and S, and the content of the halogen element is about 0.01 atom % to 5 atom %. The content of the halogen element is preferably about 0.5 atom % or more and 2 atom % or less. A unit of “atom %” is a ratio when the number of all atoms constituting the quantum dots 5 is 100. A halogen element amount can be measured by EDX analysis.

In the quantum dot light-emitting diode (QLED) using the quantum dots 5 of the present embodiment, the external quantum efficiency (EQE) can be effectively improved. In the present embodiment, the EQE can be 7% or more. The EQE can be preferably 9% or more, more preferably 9.5% or more, still more preferably 10% or more, and still further more preferably 10.5% or more. The EQE can be evaluated using an LED measuring device, and is obtained as a maximum value.

In addition, the EQE can be improved by increasing QY as shown in the above (Formula 1). Accordingly, in order to obtain the high EQE, it is preferable to increase the QY of the quantum dots 5. In the present embodiment, the QY can be 70% or more, preferably 75% or more, more preferably 80% or more, still more preferably 85% or more, still further more preferably 90% or more, and most preferably 95% or more.

The quantum dots 5 of the present embodiment preferably have a fluorescence half-value width of 20 nm or less. The “fluorescence half-value width” refers to a full width at half maximum indicating a spread of the fluorescence wavelength at half of a peak value of a fluorescence intensity in the fluorescence spectrum. In addition, the fluorescence half-value width is more preferably 15 nm or less. As described above, in the present embodiment, since the fluorescence half-value width can be narrowed, it is possible to improve the high color gamut.

In the present embodiment, as to be described later, copper chalcogenide is synthesized as a precursor as a reaction system for synthesizing the quantum dots 5, and then the metal exchange reaction is performed on the precursor. By manufacturing the quantum dots 5 based on such an indirect synthesis reaction, the fluorescence half-value width can be narrowed.

In addition, in the present embodiment, a fluorescence lifetime of the quantum dots 5 can be set to 50 ns or less. Alternatively, in the present embodiment, the fluorescence lifetime can be adjusted to 40 ns or less, 30 ns or less, or 20 ns or less. As described above, in the present embodiment, the fluorescence lifetime can be shortened, but also can be extended to about 50 ns, and the fluorescence lifetime can be adjusted depending on use applications.

In the present embodiment, the fluorescence wavelength can be freely controlled to about 410 nm or more and 470 nm or less. Specifically, the quantum dots 5 in the present embodiment is a solid solution based on ZnSe. In the present embodiment, the fluorescence wavelength can be controlled by adjusting the particle size of the quantum dots 5 and the composition of the quantum dots 5. In the present embodiment, the fluorescence wavelength can be preferably 430 nm or more, and more preferably 440 nm or more.

As described above, in the quantum dots 5 of the present embodiment, the fluorescence wavelength can be controlled to be blue.

Subsequently, a method for manufacturing the quantum dots 5 of the present embodiment will be described. The method for manufacturing the quantum dots 5 according to the present embodiment includes a step of generating a core and a step of coating the surface of the core with a shell, and the step of coating the shell is characterized in that an acidic compound and a zinc halide compound are blended in the shell raw material.

### <Synthesis Method of Core>

A synthesis method of core will be described. First, in the present embodiment, a copper chalcogenide precursor is synthesized from an organic copper compound or an inorganic copper compound, and an organic chalcogen compound. Specifically, the copper chalcogenide precursor is preferably Cu₂Se, Cu₂SeS, Cu₂SeTe, or Cu₂SeTeS.

Here, in the present embodiment, the Cu raw material is not particularly limited, but for example, the following organic copper reagent or inorganic copper reagent can be used. In other words, copper acetate (I): Cu(OAc), copper acetate (II): Cu(OAc)₂ as acetate salts, and copper stearate: Cu(OC(═O)C₁₇H₃₅)₂, copper oleate: Cu(OC(═O)C₁₇H₃₃)₂, copper myristate: Cu(OC(═O)C₁₃H₂₇)₂, copper dodecanoate: Cu(OC(═O)C₁₁H₂₃)₂, copper acetylacetonate: Cu(acac)₂ as fatty acid salts, and both monovalent and divalent compounds can be used as halides, and copper chloride (I): CuCl, copper chloride (II): CuCl₂, copper bromide (I): CuBr, copper bromide (II): CuBr₂, and copper iodide (I): CuI, copper iodide (II): CuI₂ or the like can be used.

In the present embodiment, a Se raw material uses an organic selenium compound (an organic chalcogenide) as a raw material. Although a structure of the compound is not particularly limited, for example, trioctylphosphine selenide in which Se is dissolved in trioctylphosphine: (C₈H₁₇)₃P═Se, tributylphosphine selenide in which Se is dissolved in tributylphosphine: (C₄H₉)₃P═Se, or the like can be used. Alternatively, a solution (Se-ODE) obtained by dissolving Se at a high temperature in a high-boiling point solvent that is a long-chain hydrocarbon such as octadecene, or a solution (Se-DDT/OLAm) obtained by dissolving Se in a mixture of oleylamine and dodecanethiol can be used.

In the present embodiment, Te uses an organic tellurium compound (an organic chalcogen compound) as a raw material. Although the structure of the compound is not particularly limited, for example, trioctylphosphine telluride: (C₈H₁₇)₃P═Te in which Te is dissolved in trioctylphosphine, tributylphosphine telluride: (C₄H₉)₃P═Te in which Te is dissolved in tributylphosphine, or the like can be used. In addition, it is also possible to use dialkyl ditelluride: R₂Te₂ such as diphenyl ditelluride: (C₆H₅)₂Te₂.

In the present embodiment, the organic copper compound or the inorganic copper compound, and the organic chalcogen compound are mixed and dissolved. As the solvent, octadecene can be used as a saturated hydrocarbon having a high boiling point or an unsaturated hydrocarbon. In addition to this, t-butylbenzene: t-butylbenzene can be used as an aromatic high-boiling point solvent, and butyl butyrate: C₄H₉COOC₄H₉, benzyl butyrate: C₆H₅CH₂COOC₄H₉ and the like can be used as a high-boiling point ester-based solvent. However, an aliphatic amine-based compound, a fatty acid-based compound, an aliphatic phosphorus-based compound, or a mixture thereof can also be used as a solvent.

At this time, a reaction temperature is set to a range of 140° C. or higher and 250° C. or lower to synthesize the copper chalcogenide precursor. Note that the reaction temperature is preferably 140° C. or higher and 220° C. or lower at a lower temperature, and more preferably 140° C. or higher and 200° C. or lower at a further lower temperature.

In addition, in the present embodiment, a reaction method is not particularly limited, but it is important to synthesize Cu₂Se, Cu₂SeS, Cu₂SeTe, and Cu₂SeTeS having uniform particle sizes in order to obtain a quantum dot having a narrow fluorescence half-value width.

Next, as a raw material of ZnSe, ZnSeS, ZnSeTe, or ZnSeTeS, an organic zinc compound or an inorganic zinc compound is prepared. The organic zinc compound and the inorganic zinc compound are stable and easily handled raw materials even in air. The structure of the organic zinc compound or the inorganic zinc compound is not particularly limited, but it is preferable to use a highly ionic zinc compound in order to efficiently perform the metal exchange reaction. For example, the following organic zinc compound and inorganic zinc compound can be used. In other words, zinc acetate: Zn(OAc)₂, zinc nitrate: Zn(NO₃)₂ as acetate salts, zinc stearate: Zn(OC(═O)C₁₇H₃₅)₂, zinc oleate: Zn(OC(═O)C₁₇H₃₃)₂, zinc palmitate: Zn(OC(═O)C₁₅H₃₁)₂, zinc myristate: Zn(OC(═O)C₁₃H₂₇)₂, zinc dodecanoate: Zn(OC(═O)C₁₁H₂₃)₂, zinc acetylacetonate: Zn(acac)₂ as fatty acid salts, zinc chloride: ZnCl₂, zinc bromide: ZnBr₂, zinc iodide: ZnI₂ as halides, zinc diethyldithiocarbamate: Zn(SC(═S)N(C₂H₅)₂)₂, Zinc dimethyldithiocarbamate: Zn(SC(═S)N(CH₃)₂)₂, zinc dibutyldithiocarbamate: Zn(SC(═S)N(C₄H₉)₂)₂ as zinc carbamate, and the like can be used.

Subsequently, the organic zinc compound or the inorganic zinc compound is added to a reaction solution in which the copper chalcogenide precursor has been synthesized. As a result, it causes the metal exchange reaction between Cu and Zn of the copper chalcogenide. The metal exchange reaction is preferably caused at 150° C. or more and 300 or less. In addition, the metal exchange reaction is more preferably caused at a lower temperature of 150° C. or more and 280° C. or less, still more preferably 150° C. or more and 250° C. or less.

In the present embodiment, it is preferable that the metal exchange reaction between Cu and Zn proceeds quantitatively, and the precursor Cu is not contained in the nanocrystal. This is because when Cu of the precursor remains in the nanocrystal, Cu acts as a dopant and emits light by another light-emitting mechanism to increase the fluorescence half-value width. Residual amount of Cu is preferably 100 ppm or less, more preferably 50 ppm or less, and ideally 10 ppm or less with respect to Zn.

In the present embodiment, the residual amount of Cu in the ZnSe-based quantum dot synthesized by the cation exchange method tends to be higher than that in the ZnSe-based quantum dot synthesized by a direct method, but good light emission characteristics can be obtained even when Cu is contained in an amount of about 1 to 10 ppm with respect to Zn. Note that it is possible to determine that the quantum dot is synthesized by the cation exchange method based on the residual amount of Cu. In other words, through synthesizing by the cation exchange method, the particle size can be controlled by the copper chalcogenide precursor, and a synthesis method that is inherently difficult to react becomes possible, and thus the residual amount of Cu is advantageous in determining whether or not the cation exchange method is used.

In addition, in the present embodiment, a compound is required having an auxiliary role of releasing the metal of the copper chalcogenide precursor into the reaction solution by coordination, chelate, or the like when performing metal exchange.

Examples of the compound having the above-described role include a ligand capable of forming a complex with Cu. For example, phosphorus-based ligands, amine-based ligands, and sulfur-based ligands are preferable, and among them, the phosphorus-based ligands are more preferable because of their high efficiency.

As a result, the metal exchange between Cu and Zn is appropriately performed, and a quantum dot having a narrow fluorescence half-value width based on Zn and Se can be manufactured. In the present embodiment, quantum dots are possible for mass production with the cation exchange method as compared with a direct synthesis method.

In other words, in the direct synthesis method, for example, an organic zinc compound such as diethyl zinc (Et₂Zn) is used in order to enhance the reactivity of a Zn raw material. However, since diethyl zinc has the high reactivity and needs to be handled under an inert gas flow because it ignites in the air, it is difficult to handle and store raw materials, and a reaction using the raw materials also involves risks such as heat generation and ignition, and therefore it is not suitable for mass production. In addition, similarly, in order to enhance the reactivity of the Se raw material, for example, a reaction using selenium hydride (H₂Se) or the like is also not suitable for mass production from a viewpoint of toxicity and safety.

In addition, in a reaction system using a highly reactive Zn raw material or Se raw material as described above, although ZnSe is generated, particle generation is not controlled, and as a result, the fluorescence half-value width of the generated ZnSe is widened.

On the other hand, in the present embodiment, a copper chalcogenide precursor is synthesized from an organic copper compound or an inorganic copper compound and an organic chalcogen compound, and metal exchange is performed using the copper chalcogenide precursor to synthesize the quantum dots. As described above, in the present embodiment, to start with, the quantum dots are synthesized through the synthesis of the copper chalcogenide precursor, and are not directly synthesized. By such indirect synthesis, it is not necessary to use a reagent that is too highly reactive and is dangerous to handle, and it is possible to safely and stably synthesize a ZnSe-based quantum dot having a narrow fluorescence half-value width.

In addition, in the present embodiment, the metal exchange between Cu and Zn is performed in one pot without isolating or purifying the copper chalcogenide precursor, and quantum dots having desired composition and particle size can be obtained. On the other hand, the copper chalcogenide precursor may be used after being isolated and purified once.

In addition, in the present embodiment, the synthesized quantum dots exhibit fluorescence characteristics without performing various treatments such as washing, isolation and purification, coating treatment, and ligand exchange.

### <Method for Synthesizing Shell>

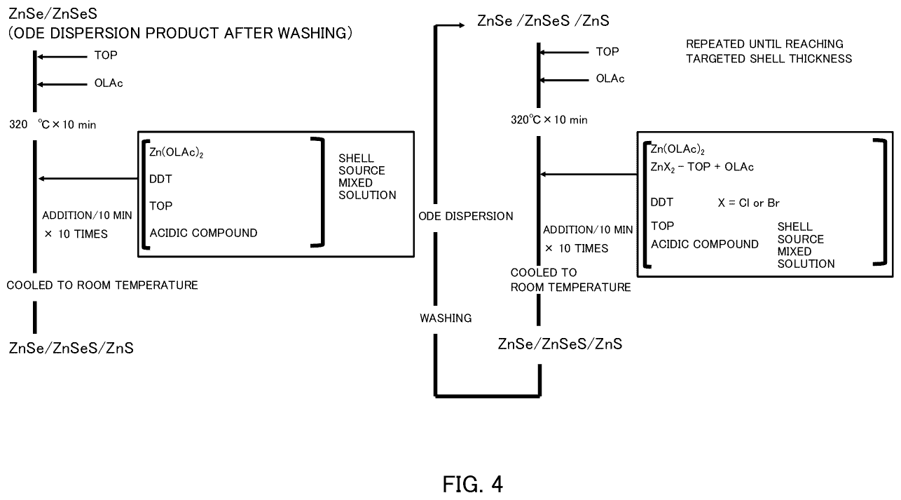

A method for synthesizing the shell will be described with reference to a flowchart illustrated in FIG. 4. In the present embodiment, for example, after a ZnSe core is synthesized, the surface of the ZnSe core is coated with, for example, ZnSeS. For coating of ZnSeS, for example, a mixed solution of a Se-TOP solution, an S-TOP solution, and the zinc oleate is added to a solution in which the ZnSe core is dispersed, and heating is performed at a predetermined temperature while stirring. By repeating this operation a plurality of times, the surface of ZnSe can be coated with ZnSeS.

In the present embodiment, after washing, ZnSe/ZnSeS is dispersed in, for example, octadecene (ODE), trioctylphosphine (TOP) and oleic acid are further added, and the mixture is stirred and heated under predetermined heat treatment conditions (for example, 320° C.×10 minutes).

Next, in the present embodiment, a ZnS shell is coated. In the present embodiment, the step of coating the ZnS shell is preferably performed separately at least in the first half and the second half. To start with, in the first half step of covering the ZnS shell, a shell source mixed solution (the shell raw material) blending the acidic compound is added to a solution in which ZnSe/ZnSeS is dispersed. Specifically, a zinc oleate (Zn(OLAc)₂) solution, dodecanethiol (DDT) and TOP are added, and an acidic oxide is further added. In the present embodiment, the shell source mixed solution containing the acidic oxide is added and heated while being stirred under predetermined heating conditions. The predetermined heating conditions are, for example, a heating temperature of 320° C. and a heating time of 10 minutes. In the present embodiment, the operation of adding and heating the shell source mixed solution is repeatedly performed a plurality of times. In FIG. 4, the number of repetitive operations is described as 10, but “10” is an example, and the number of repetitive operations is not limited. However, the number of repetitions is preferably defined within a range of about 5 to 15. Thereafter, cooling is performed to room temperature.

In the present embodiment, in the first half shell coating step, the acidic compound is added to the shell source mixed solution, but the zinc halide compound to be blended in the second half shell coating step is not added. It has been found that adding the zinc halide compound to the shell source mixed solution in the first shell coating step causes QY to decrease. Therefore, in the first half shell coating step, the zinc halide compound is not added to the shell source mixed solution.

Next, in the present embodiment, the second half of the shell coating step is performed. In the second half of the shell coating step, the shell source mixed solution containing the acidic compound and the zinc halide compound is added to the solution in which ZnSE/ZnSeS/ZnS is dispersed. The zinc halide compound and the acidic compound are added to the shell source mixed solution together with, for example, the zinc oleate (Zn(OLAc)₂) solution, dodecanethiol (DDT), and TOP. As described above, in the second half of the shell coating step, the shell source mixed solution containing the acidic compound and the zinc halide compound is added and heated while being stirred under predetermined heating conditions. The predetermined heating conditions are, for example, a heating temperature of 320° C. and a heating time of 10 minutes. In the present embodiment, the operation of adding and heating the shell source mixed solution is repeatedly performed a plurality of times. In FIG. 4, the number of repetitive operations is described as 10, but “10” is an example and the number of repetitive operations is not limited. However, the number of repetitions is preferably defined within a range of about 5 to 15.

Thereafter, the mixture is cooled to room temperature, washed, and further dispersed by an addition of ODE. The step from the addition of the shell source mixed solution to the ODE dispersion is repeated until a predetermined shell thickness is obtained.

As described above, the second half of the shell coating step is characterized by adding the shell source mixed solution containing the acidic compound and the zinc halide compound.

In the present embodiment, it is intended to improve the EQE, but for this purpose, it is necessary to improve the QY and further optimize the particle shape. If the QY can be increased, the EQE can be improved as shown in (Formula 1).

The optimization of the particle shape will be described as follows. In other words, when the distance between the cores of the quantum dots is short, the Forster resonance energy (FRET) is generated, leading to a decrease in the EQE. Therefore, it is considered that the cores can be physically separated from each other and the FRET can be reduced by adopting the core-shell structure in which the shell is covered around the core. However, when the shell thickness is increased, the particle shape has been deteriorated, and accordingly, the QY has also been decreased. In addition, conventionally, there has been a problem that the entire surface of the core cannot be covered with the shell at a predetermined thickness and defects occur, or the shell thickness locally increases and the particle shape deteriorates. As a result, the FRET cannot be appropriately reduced, and the EQE cannot be effectively reduced.

Thereupon, in the present embodiment, the QY can be improved by adding the zinc halide compound to the core little by little. In particular, by adding the zinc halide compound only to the second half of the shell coating step without adding the zinc halide compound to the first half of the shell coating step, the QY can be effectively improved. In addition, when the shell source mixed solution is continuously added, the particle shape is deteriorated. Thus, by adding the acidic compound to the shell source mixed solution, the portion of the shell having a large thickness is locally etched to adjust the shape, and it is possible to align the shape to a good particle shape having a polygonal cross section.

In the present embodiment, it is preferable to add the zinc halide compound in an amount of about 0.5 mol % to 3 mol %, and it is more preferable to add the zinc halide compound in an amount of about 1 mol % to 2 mol % with respect to the zinc oleate.

In the present embodiment, at least one acidic compound can be selected from hydrogen chloride (HCl), hydrogen bromide (HBr), hydrogen iodide (HI), trifluoroacetic acid (TFA), trifluoromethanesulfonic acid (TfOH), acetic acid (AA), sulfuric acid (H₂SO₄), phosphoric acid (H₃PO₄), and the like. Among them, it is preferable to use at least one of hydrogen chloride (HCl), hydrogen bromide (HBr), and trifluoroacetic acid (TFA). A high QY can be obtained, and the particle shape of the quantum dots can be improved. In the present embodiment, for example, a hydrogen oxide-ethyl acetate solution can be added to the shell source mixed solution.

In the present embodiment, it is preferable to use the zinc chloride (ZnCl₂) or at least one of the zinc bromide (ZnBr₂), zinc fluoride (ZnF₂), or zinc iodide (ZnI₂) as the zinc halide compound. In the present embodiment, for example, a zinc chloride-TOP-oleic acid solution can be added to the shell source mixed solution.

In addition, in the present embodiment, an S raw material used for the core-shell structure is not particularly limited, but typical examples thereof include the following raw materials.

In other words, as the thiols, a solution (S-TOP) obtained by dissolving sulfur in a high-boiling point solvent that is a long-chain phosphine-based hydrocarbon such as octadecanethiol: C₁₈H₃₇SH, hexane decanethiol: C₁₆H₃₃SH, tetradecanethiol: C₁₄H₂₉SH, dodecanethiol: C₁₂H₂₅SH, decanethiol: C₁₀H₂₁SH, octanethiol: C₈H₁₇SH, benzenethiol: C₆H₅SH, or trioctylphosphine, further, a solution (S-ODE) obtained by dissolving sulfur in a high-boiling point solvent that is a long-chain hydrocarbon such as octadecene, or a solution (S-DDT/OLAm) obtained by dissolving sulfur in a mixture of oleylamine and dodecanethiol, or the like can be used.

The reactivity varies depending on the S raw material to be used, and as a result, a coating thickness of the shell 5b (for example, ZnS) can be made varied. Thiol based are proportional to their rate of degradation, and S-TOP or S-ODE has a changing reactivity proportional to their stability. Thus, the coating thickness of the shell 5b can be controlled by using the S raw materials, and the final fluorescence quantum yield can also be controlled.

In addition, in the present embodiment, as the amount of an amine-based solvent used for coating the shell 5b is smaller, the coating of the shell 5b becomes easier, and favorable light emission characteristics can be obtained. Furthermore, the light emission characteristics after coating of the shell 5b vary depending on a ratio of the amine-based solvent, a carboxylic acid-based solvent, or a phosphine-based solvent.

Furthermore, the quantum dots 5 synthesized by the manufacturing method of the present embodiment can be aggregated by adding a polar solvent such as methanol, ethanol, or acetone, and the quantum dots 5 and unreacted raw materials can be separated and recovered. Toluene, hexane, or the like is added again to the recovered quantum dots 5 to disperse the quantum dots again. By adding a solvent serving as a ligand to the re-dispersed solution, the light emission characteristics can be further improved and the stability of the light emission characteristics can be improved. The change in the light emission characteristics due to the addition of this ligand greatly varies depending on presence or absence of a coating operation of the shell 5b, and in the present embodiment, the quantum dots 5 coated with the shell 5b can particularly improve fluorescence stability by adding the thiol-based ligand.

The application of the quantum dots 5 shown in FIGS. 1A and 1B is not particularly limited, but for example, the quantum dots 5 of the present embodiment that emit the blue fluorescence can be applied to a wavelength conversion member, an illumination member, a backlight device, a display device, and the like.

When the quantum dots 5 of the present embodiment are applied to a part of the wavelength conversion member, the illumination member, the backlight device, the display device, and the like, and for example, the photoluminescence (PL) is adopted as the light emission principle, the blue fluorescence can be emitted by UV irradiation from a light source. Alternatively, when electroluminescence (EL) is adopted as the light emission principle, or in a case where all three primary colors are caused to emit quantum dots through another method, a light-emitting element that emits the blue fluorescence using the quantum dots 5 of the present embodiment can be used. In the present embodiment, a light-emitting element (a full color LED) including the quantum dots 5 of the present embodiment that emit the blue fluorescence together with the quantum dots that emit green fluorescence and the quantum dots that emits red fluorescence can emit white light.

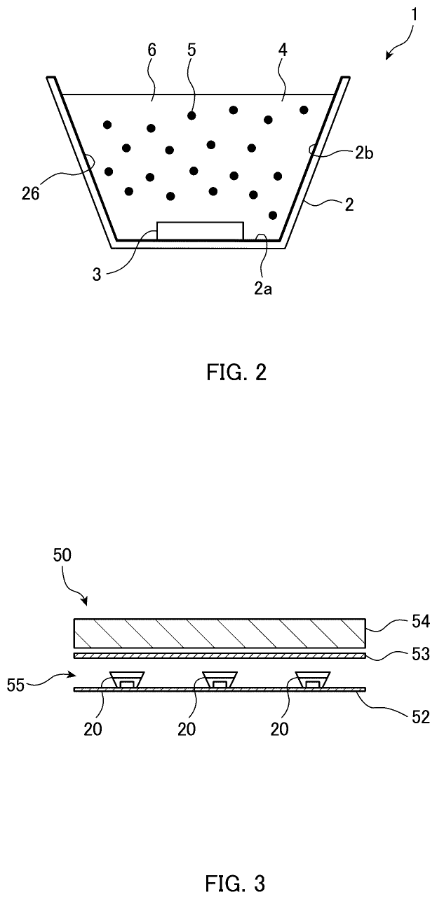

FIG. 2 is the schematic diagram of the LED device using the quantum dots of the present embodiment. As illustrated in FIG. 2, an LED device 1 of the present embodiment includes a storage case 2 having a bottom surface 2a and a side wall 2b surrounding a periphery of the bottom surface 2a, an LED chip (a light-emitting element) 3 disposed on the bottom surface 2a of the storage case 2, and a fluorescent layer 4 filling the storage case 2 and sealing the upper surface side of the LED chip 3. Here, the upper surface side is a direction in which light emitted from the LED chip 3 is emitted from the storage case 2, and indicates a direction opposite to the bottom surface 2a with respect to the LED chip 3.

The LED chip 3 may be disposed on a base wiring board (not illustrated), and the base wiring board may constitute a bottom surface portion of the storage case 2. As a base substrate, for example, a configuration in which a wiring pattern is formed on a base material such as a glass epoxy resin can be presented.

The LED chip 3 is a semiconductor element that emits light when a voltage is applied in a forward direction, and has a basic configuration in which a P-type semiconductor layer and an N-type semiconductor layer are PN bonded.

As shown in FIG. 2, the fluorescent layer 4 is formed of a resin 6 in which a large number of quantum dots 5 are dispersed.

Furthermore, the resin composition in which the quantum dots 5 are dispersed in the present embodiment may contain a fluorescent substance different from that of the quantum dots 5. Examples of the fluorescent substance include sialon-based fluorescent substances and KSF (K₂SiF₆: Mn⁴⁺) red fluorescent substances, but the material thereof is not particularly limited.

The resin 6 constituting the fluorescent layer 4 is not particularly limited, but polypropylene (PP), polystyrene (PS), acrylic resin, methacrylate, MS resin, polyvinyl chloride (PVC), polycarbonate (PC), polyethylene terephthalate (PET), polyethylene naphthalate (PEN), polymethylpentene, liquid crystal polymer, epoxy resin, silicone resin, or a mixture thereof can be used.

The LED device using the quantum dots of the present embodiment can be applied to the display device. FIG. 3 is the longitudinal sectional view of the display device using the LED device illustrated in FIG. 2. As illustrated in FIG. 3, a display device 50 includes a plurality of LED devices 20 and a display unit 54 such as a liquid crystal display facing each LED device 20. Each LED device 20 is arranged on a back surface side of the display unit 54. Similarly to the LED device 1 illustrated in FIG. 2, each LED device 20 has a structure in which an LED chip is sealed with a resin obtained by diffusing the large number of quantum dots 5.

As illustrated in FIG. 3, the plurality of LED devices 20 are supported by a support 52. The LED devices 20 are arranged at predetermined intervals. Each LED device 20 and the support 52 constitute a backlight 55 for the display unit 54. The support 52 has a sheet shape, a plate shape, a case shape, or the like, and is not particularly limited in shape or material. As illustrated in FIG. 3, a light diffusion plate 53 or the like may be interposed between the backlight 55 and the display unit 54.

By applying the quantum dots 5 in the present embodiment to the LED device shown in FIG. 2, the display device shown in FIG. 3, and the like, the light emission characteristics of the device can be effectively improved. In particular, the EQE can be improved when the quantum dots of the present embodiment are applied to a QLED element. In the present embodiment, the EQE of 7% or more can be obtained, preferably 9% or more, more preferably 10% or more, and still more preferably 10.5% or more can be obtained.

In addition, a resin composition in which the quantum dots 5 of the present embodiment are dispersed in a resin can also be formed into a sheet shape or a film shape. Such a sheet or film can be incorporated into, for example, a backlight device.

In addition, in the present embodiment, the wavelength conversion member in which the plurality of quantum dots are dispersed in the resin can be formed as a molded body. For example, the molded body in which the quantum dots are dispersed in the resin is stored in a container having a storage space by press-fitting or the like. At this time, a refractive index of the molded body is preferably smaller than a refractive index of the container. As a result, part of the light entering the molded body is totally reflected by an inner wall of the container. Accordingly, beams of light leaking from a side of the container to outside can be reduced. As described above, by applying the quantum dots in the present embodiment to the wavelength conversion member, the illumination member, the backlight device, the display device, and the like, the light emission characteristics can be effectively improved.

### EXAMPLES

Hereinafter, effects of the present invention will be described with reference to the examples and comparative examples of the present invention. Note that the present invention is not limited by the following examples at all.

In the present invention, the following raw materials were used in synthesizing Cd-free blue fluorescent quantum dots. Furthermore, in evaluating the synthesized quantum dots, the following measuring instruments were used.

### <Raw Materials>

Copper acetate anhydride: manufactured by Wako Pure Chemical Industries, Ltd.

Octadecene: manufactured by Idemitsu Kosan Co., Ltd.

Orelamine: phamine manufactured by Kao Corporation

Oleic acid: LUNAC O-V manufactured by Kao Corporation

Dodecanethiol (DDT): Thiocarcol 20 manufactured by Kao Corporation

Trioctylphosphine (TOP): manufactured by Hokko Chemical Industry Co., Ltd.

Anhydrous zinc acetate: manufactured by Kishida Chemical Co., Ltd.

Selenium (4N: 99.99%): manufactured by Shinko Chemical Co., Ltd.

Sulfur: manufactured by Kishida Chemical Co., Ltd.

Hydrogen chloride: manufactured by KOKUSAN CHEMICAL CO., LTD.

Zinc chloride: manufactured by Kanto Chemical CO., INC.

Hydrogen bromide: manufactured by Tokyo Chemical Industry Co., Ltd.

Zinc bromide: manufactured by Kishida Chemical Co., Ltd.

### <Measuring Instruments>

Fluorescence spectrometer: F-2700 manufactured by JASCO Corporation

UV-visible spectrophotometer: V-770 manufactured by Hitachi, Ltd.

Fluorescence quantum yield measuring device: QE-1100 manufactured by Otsuka Electronics Co., Ltd.

X-ray diffractometer (XRD): D2 PHASER manufactured by Bruker Corporation

Scanning electron microscope (SEM): SU9000 manufactured by Hitachi, Ltd.

Fluorescence life measuring device: C11367 manufactured by Hamamatsu Photonics K.K.

LED measuring device: manufactured by SPECTRA CO-OP

Transmission electron microscope (TEM): JEM-ARM200-CF manufactured by JEOL Ltd.

XEDS detector: JED2300T manufactured by JEOL Ltd.

### Example 1

### <Synthesis Method of ZnSe Core>

A reaction vessel of 300 mL was charged with 728 mg of copper acetate anhydride: Cu(OAc)₂, 19.2 mL of oleylamine: OLAm, and 31 mL of octadecene: ODE. Then, the mixture was heated at 165° C. for 20 minutes under an inert gas (N₂) atmosphere with stirring to dissolve the raw materials.

To this solution was added 4.56 mL of a Se-DDT/OLAm solution (0.7 M) and heated at 165° C. for 30 minutes with stirring. The obtained reaction solution (CuSe) was cooled to room temperature.

Thereafter, 7376 mg of anhydrous zinc acetate: Zn(OAc)₂, 40 mL of trioctylphosphine: TOP, and 1.6 mL of oleylamine: OLAm were added to a CuSe reaction solution, and the mixture was heated at 200° C. for 1 hour under an inert gas (N₂) atmosphere with stirring. The obtained reaction solution (ZnSe) was cooled to room temperature.

Ethanol was added to the reaction solution that has been cooled to room temperature to generate a precipitate, the precipitate was recovered by centrifugation, and 96 ml of octadecene: ODE was added to and dispersed in the precipitate.

Thereafter, 7376 mg of anhydrous zinc acetate: Zn(OAc)₂, 40 mL of trioctylphosphine: TOP, 4 mL of oleylamine: OLAm, and 24 mL of oleic acid: OLAc were added in 96 ml of a ZnSe-ODE solution, and the mixture was heated at 290° C. for 30 minutes under an inert gas (N₂) atmosphere with stirring. The obtained reaction solution (ZnSe) was cooled to room temperature.

The obtained reaction solution was measured with a fluorescence spectrometer. As a result, the optical characteristics were obtained in which the fluorescence wavelength was about 446.5 nm and the fluorescence half-value width was about 14 nm.

<Method for Coating ZnSe Core with Shell>

Ethanol was added to 40 ml of the ZnSe reaction solution to generate a precipitate, the precipitate was recovered by centrifugation, and 35 ml of octadecene: ODE was added to and dispersed in the precipitate.

To 35 mL of the dispersed ZnSe-ODE solution were added 2 mL of oleic acid: OLAc and 4 mL of trioctylphosphine: TOP, and the mixture was heated at 320° C. for 10 minutes under an inert gas (N₂) atmosphere with stirring.

To this solution, a mixed solution including 0.5 mL of a Se-TOP solution (1 M), 0.5 mL of an S-TOP solution (1 M), and 5 mL of a zinc oleate: Zn(OLAc)₂ solution (0.4 M) was added in an amount of 0.9 mL, and the mixture was heated at 320° C. for 10 minutes with stirring. This operation was repeated four times.

Thereafter, ethanol was added to the obtained reaction solution to generate a precipitate, the precipitate was recovered by centrifugation, and 35 ml of octadecene: ODE was added to and dispersed in the precipitate. Then, 2 mL of oleic acid: OLAc and 4 mL of trioctylphosphine: TOP were added in the same manner as above, and heated at 320° C. for 10 minutes under an inert gas (N₂) atmosphere with stirring.

To this solution, 0.9 mL of a mixed solution of 0.4 mL of DDT, 1.6 mL of trioctylphosphine: TOP, 0.12 mL of a hydrogen chloride-ethyl acetate solution (4 M), and 10 mL of a zinc oleate: Zn(OLAc)₂ solution (0.4 M) was added, and the mixture was heated at 320° C. for 10 minutes with stirring. This operation was repeated ten times.

Thereafter, ethanol was added to the obtained reaction solution to generate a precipitate, the precipitate was recovered by centrifugation, and 35 ml of octadecene: ODE was added to and dispersed in the precipitate. Then, 2 mL of oleic acid: OLAc and 4 mL of trioctylphosphine: TOP were added in the same manner as above, and heated at 320° C. for 10 minutes under an inert gas (N₂) atmosphere with stirring.

To this solution, a mixed solution including 0.4 mL of DDT, 1.6 mL of trioctylphosphine: TOP, 0.12 mL of a hydrogen chloride-ethyl acetate solution (4 M), 0.1 mL of a zinc chloride-TOP-oleic acid solution (0.8 M), and 10 mL of a zinc oleate: Zn(OLAc)₂ solution (0.4 M) was added in an amount of 0.9 mL, and the mixture was heated at 320° C. for 10 minutes with stirring. This operation was repeated ten times.

Thereafter, ethanol was added to the obtained reaction solution to generate a precipitate, the precipitate was recovered by centrifugation, and 35 ml of octadecene: ODE was added to and dispersed in the precipitate. Then, 2 mL of oleic acid: OLAc and 4 mL of trioctylphosphine: TOP were added in the same manner as above, and heated at 320° C. for 10 minutes under an inert gas (N₂) atmosphere with stirring.

To this solution, a mixed solution including 0.4 mL of DDT, 1.6 mL of trioctylphosphine: TOP, 0.2 mL of a hydrogen chloride-ethyl acetate solution (4 M), 0.1 mL of a zinc chloride-TOP-oleic acid solution (0.8 M), and 10 mL of a zinc oleate: Zn(OLAc)₂ solution (0.4 M) was added in an amount of 0.9 mL, and the mixture was heated at 320° C. for 10 minutes with stirring. This operation was repeated ten times.

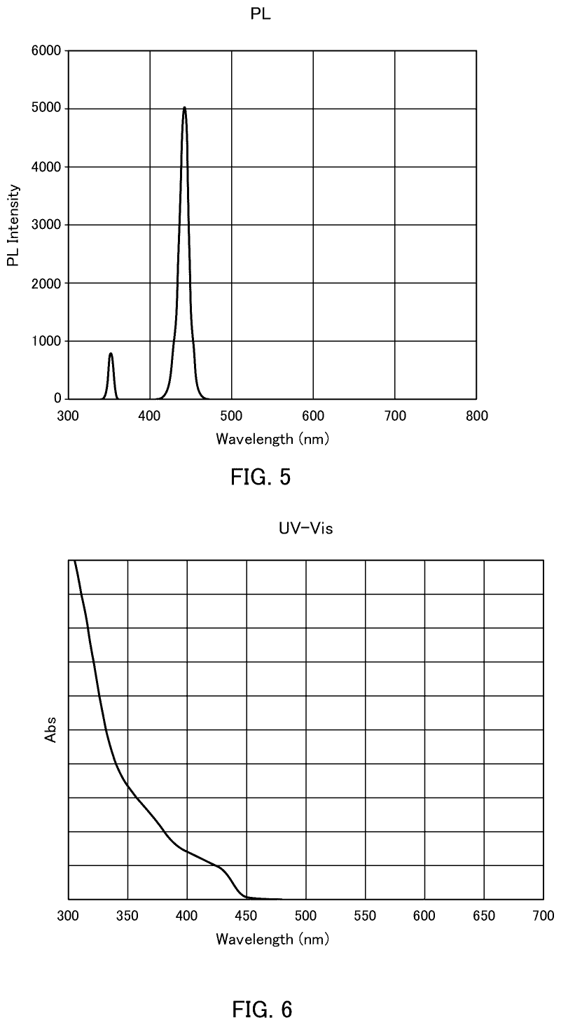

The obtained reaction solution was measured with a fluorescence spectrometer. As a result, as shown in FIG. 5, the optical characteristics were obtained in which the fluorescence wavelength was about 442 nm and the fluorescence half-value width was about 15 nm.

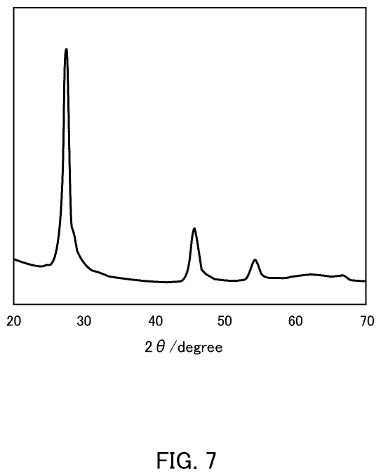

Ethanol was added to the obtained reaction solution to generate a precipitate, the precipitate was recovered by centrifugation, and hexane was added to and dispersed in the precipitate. The obtained dispersion solution was measured with an ultraviolet-visible spectrometer. As a result, an ultraviolet-visible absorption spectrum in FIG. 6 was obtained. FIG. 7 is an X-ray diffraction (XRD) spectrum of Example 1. From the results of FIG. 7, a crystal peak of a cubic crystal composed of Zn, Se, and S could be confirmed.

### <Measurement Results>

Hexane-dispersed ZnSe/ZnSeS/ZnS was measured with a quantum efficiency measurement system. As a result, the fluorescence quantum yield was about 96%. In addition, as a result of measuring the fluorescence lifetime, it was 16 ns. As a result of the elemental analysis (EDX), Zn: 42 atom %, Se: 11 atom %, S: 41 atom %, and Cl: 1 atom % were obtained. As a result of analyzing the image obtained by TEM, a thickness of the shell was 2.0 nm.

In addition, the quantum dots obtained in Example 1 were applied to manufacture a light-emitting element having the following stacked structure.

ITO/PEDOT: PSS/PVK/QD Layer/LiZnO/Al

The present element was evaluated using an LED measuring device, and as a result, the maximum value of the external quantum efficiency (EQE) was 18.6%.

### Example 2

Synthesis was performed under the same conditions as in Example 1 except that the zinc chloride-TOP-oleic acid solution used in Example 1 was changed to a zinc bromide-TOP-oleic acid solution.

### Example 3

Synthesis was performed under the same conditions as in Example 2 except that the hydrogen chloride-ethyl acetate solution (4M) (see the descriptions of Example 1) used in Example 2 was changed to a hydrogen bromide-acetic acid solution.

### Example 4

Synthesis was performed under the same conditions as in Example 1 except that the hydrogen chloride-ethyl acetate solution (4M) used in Example 1 was changed to trifluoroacetic acid.

### Example 5

Synthesis was performed under the same conditions as in Example 2 except that the hydrogen chloride-ethyl acetate solution (4M) used in Example 2 (see the descriptions of Example 1) was changed to trifluoroacetic acid.

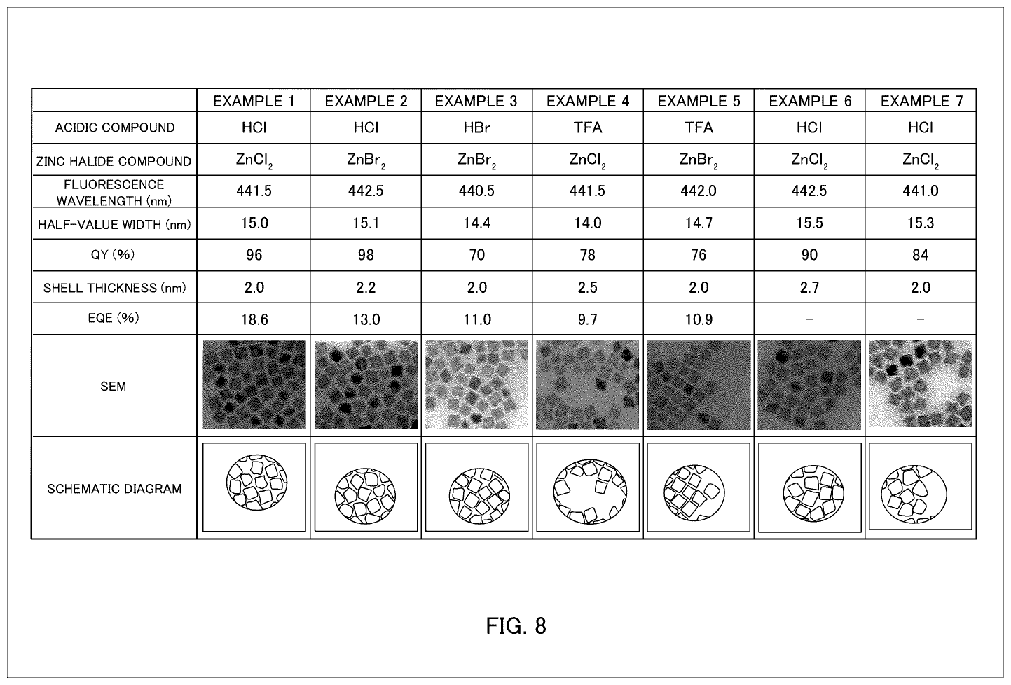

FIG. 8 is a table summarizing the measurement results of Examples 1 to 5. In addition, TEM photographs of the quantum dots obtained in Examples 1 to 5 are also shown.

As shown in FIG. 8, in each of Examples 1 to 5, the EQE was 7% or more. In particular, in Example 1, the EQE could be improved to 18.6%.

In addition, in any of the examples, the QY was 70% or more. In particular, in Example 2, the QY could be improved to 98%.

In addition, in each of the examples, the fluorescence half-value width could be 20 nm or less. Furthermore, in any of the examples, the fluorescence wavelength could be kept within a range of 410 nm to 470 nm, and the blue fluorescence was exhibited.

In addition, the shell thickness of each example was in the range of about 2 nm to 2.5 nm. Note that the shell thickness can be estimated from a photograph of the analysis result of TEM-EDX.

As shown in the SEM photographs of the respective examples in FIG. 8, it was found that the particle shape of the quantum dot was a substantially rectangular shape (substantially cubic shape) and was favorable. In other words, it is considered that the ZnSe core was crystallized in the substantially rectangular shape, and a shell having a predetermined thickness was covered over the entire circumference thereof, so that the substantially rectangular particle shape could be maintained. This is considered to be because the acidic compound was blended in the shell source mixed solution, thereby causing an effect of etching a portion where the particle shape was deteriorated.

### Example 6

Among the synthesis steps used in Example 1, <Method for synthesizing ZnSe core> was the same, and a part of <Method for coating ZnSe core with shell> was changed to synthesize the quantum dots. Hereinafter, <Method for coating ZnSe core with shell> of Example 6 will be described.

<Method for Coating ZnSe Core with Shell>

Ethanol was added to 40 ml of the ZnSe reaction solution to generate a precipitate, the precipitate was recovered by centrifugation, and 35 ml of octadecene: ODE was added to and dispersed in the precipitate.

To 35 mL of the dispersed ZnSe-ODE solution were added 2 mL of oleic acid: OLAc and 4 mL of trioctylphosphine: TOP, and the mixture was heated at 320° C. for 10 minutes under an inert gas (N₂) atmosphere with stirring.

To this solution, a mixed solution including 0.5 mL of a Se-TOP solution (1 M), 0.5 mL of an S-TOP solution (1 M), and 5 mL of a zinc oleate: Zn(OLAc)₂ solution (0.4 M) was added in an amount of 0.9 mL, and the mixture was heated at 320° C. for 10 minutes with stirring. This operation was repeated four times.

Thereafter, ethanol was added to the obtained reaction solution to generate a precipitate, the precipitate was recovered by centrifugation, and 35 ml of octadecene: ODE was added to and dispersed in the precipitate. Then, 2 mL of oleic acid: OLAc and 4 mL of trioctylphosphine: TOP were added in the same manner as above, and heated at 320° C. for 10 minutes under an inert gas (N₂) atmosphere with stirring.

To this solution, 0.9 mL of a mixed solution of 0.6 mL of DDT, 1.4 mL of trioctylphosphine: TOP, 0.24 mL of a hydrogen chloride-ethyl acetate solution (4 M), and 10 mL of a zinc oleate: Zn(OLAc)₂ solution (0.48 M) was added, and the mixture was heated at 320° C. for 10 minutes with stirring. This operation was repeated ten times.

Thereafter, ethanol was added to the obtained reaction solution to generate a precipitate, the precipitate was recovered by centrifugation, and 35 ml of octadecene: ODE was added to and dispersed in the precipitate. Then, 2 mL of oleic acid: OLAc and 4 mL of trioctylphosphine: TOP were added in the same manner as above, and heated at 320° C. for 10 minutes under an inert gas (N₂) atmosphere with stirring.

To this solution, 0.6 mL of DDT, 1.4 mL of trioctylphosphine: TOP, 0.24 mL of a hydrogen chloride-ethyl acetate solution (4 M), 0.1 mL of a zinc chloride-TOP-oleic acid solution (0.8 M), and 10 mL of a zinc oleate: Zn(OLAc)₂ solution (0.48 M) were added in an amount of 0.9 mL, and the mixture was heated at 320° C. for 10 minutes with stirring. This operation was repeated ten times.

### <Measurement Results of Example 6>

Hexane-dispersed ZnSe/ZnSeS/ZnS was measured with a quantum efficiency measurement system. As a result, the fluorescence quantum yield was about 90%. In addition, as a result of measuring the fluorescence lifetime, it was 20 ns. As a result of analyzing the image obtained by TEM, the thickness of the shell was 2.7 nm.

### Example 7

<Method for synthesizing ZnSe core> and <Method for coating ZnSe core with shell> in Example 1 were used as they were, but finally, 2.0 mL of a zinc chloride-TOP zinc chloride-TOP-oleic acid solution (0.8 M) was added, and the mixture was heated with stirring for 20 minutes.

### <Measurement Results of Example 7>

Hexane-dispersed ZnSe/ZnSeS/ZnS was measured with a quantum efficiency measurement system. As a result, the fluorescence quantum yield was about 84%. In addition, as a result of measuring the fluorescence lifetime, it was 25 ns. As a result of the elemental analysis (EDX), Zn: 32 atom %, Se: 12 atom %, S: 50 atom %, and Cl: 6 atom % were obtained. As a result of analyzing the image obtained by TEM, a thickness of the shell was 2.0 nm.

In Example 6, the shell was made thicker than that in Example 1 in order to more effectively prevent the Forster resonance energy transfer (FRET). Specifically, while the shell thickness of Example 1 was 2 nm, the shell thickness was increased to 2.7 nm in Example 6. In addition, in Example 6, a decrease in the fluorescence quantum yield (QY) could be suppressed as much as possible as compared with Example 1.

In Example 7, a chlorine content was increased for a purpose of reducing Zn with no ligand attached to the surface of the quantum dot. In other words, the Cl content of Example 7 was 6 atom % while the Cl content of Example 1 was 1 atom %.

### Comparative Example 1

Comparative Example 1 is an example in which the shell is coated without mixing the acidic compound and the zinc halide compound with the shell source mixed solution. Specifically, the shell was coated by the following steps.

A 100 mL reaction vessel was charged with 182 mg of copper acetate anhydride: Cu(OAc)₂, 4.8 mL of oleylamine: OLAm, and 7.75 mL of octadecene: ODE. Then, the mixture was heated at 165° C. for 5 minutes under an inert gas (N₂) atmosphere with stirring to dissolve the raw materials.

To this solution was added 1.14 mL of a Se-DDT/OLAm solution (0.7 M) and heated at 165° C. for 30 minutes with stirring. The obtained reaction solution (CuSe) was cooled to room temperature.

Thereafter, 1844 mg of anhydrous zinc acetate: Zn(OAc)₂, 10 mL of trioctylphosphine: TOP, and 0.4 mL of oleylamine: OLAm were added to the Cu₂Se reaction solution, and the mixture was heated at 180° C. for 45 minutes under an inert gas (N₂) atmosphere with stirring. The obtained reaction solution (ZnSe) was cooled to room temperature.

Ethanol was added to the reaction solution cooled to room temperature to generate a precipitate, the precipitate was recovered by centrifugation, and 12 ml of octadecene: ODE was added to and dispersed in the precipitate.

Thereafter, 1844 mg of anhydrous zinc acetate: Zn(OAc)₂, 10 mL of trioctylphosphine: TOP, 1 mL of oleylamine: OLAm, and 6 mL of oleic acid: OLAc were added in 12 ml of the ZnSe-ODE solution, and the mixture was heated at 280° C. for 20 minutes under an inert gas (N₂) atmosphere with stirring. The obtained reaction solution (ZnSe) was cooled to room temperature.

The obtained reaction solution was measured with a fluorescence spectrometer. As a result, the optical characteristics were obtained in which the fluorescence wavelength was about 447.5 nm and the fluorescence half-value width was about 14 nm.

Ethanol was added to 20 ml of the obtained ZnSe reaction solution to generate a precipitate, the precipitate was recovered by centrifugation, and 17.5 ml of octadecene: ODE was added to and dispersed in the precipitate.

Oleic acid: OLAc of 1 mL and trioctylphosphine: TOP of 2 mL were added to 17.5 mL of the dispersed ZnSe-ODE solution, and the mixture was heated at 320° C. for 10 minutes under an inert gas (N₂) atmosphere with stirring.

To this solution, 0.5 mL of a mixed solution of 0.5 mL of a Se-TOP solution (1 M), 0.125 mL of DDT, 0.375 mL of trioctylphosphine: TOP, and 5 mL of a zinc oleate: Zn(OLAc)₂ solution (0.4 M) was added, and the mixture was heated at 320° C. for 10 minutes with stirring. This operation was repeated four times.

Thereafter, ethanol was added to the obtained reaction solution to generate a precipitate, the precipitate was recovered by centrifugation, 17.5 ml of octadecene: ODE was added to the precipitate to disperse the precipitate, 1 mL of oleic acid: OLAc and 2 mL of trioctylphosphine: TOP were added in the same manner as above, and the mixture was heated at 320° C. for 10 minutes under an inert gas (N₂) atmosphere with stirring.

To this solution, 0.5 mL of a mixed solution of 0.5 mL of DDT, 1.5 mL of trioctylphosphine: TOP, and 10 mL of a zinc oleate: Zn(OLAc)₂ solution (0.4 M) was added, and the mixture was heated at 320° C. for 10 minutes with stirring. This operation was repeated ten times.

Thereafter, ethanol was added to the obtained reaction solution to generate a precipitate, the precipitate was recovered by centrifugation, and 17.5 ml of octadecene: ODE was added to and dispersed in the precipitate (a washing step).

Next, 1 mL of oleic acid: OLAc and 2 mL of trioctylphosphine: TOP were added in the same manner as above, and heated at 320° C. for 10 minutes under an inert gas (N₂) atmosphere with stirring. To this solution, 0.5 mL of a mixed solution of 0.5 mL of DDT, 1.5 mL of trioctylphosphine: TOP, and 10 mL of a zinc oleate: Zn(OLAc)₂ solution (0.4 M) was added, and the mixture was heated at 320° C. for 10 minutes with stirring. This operation was repeated six times. Thereafter, the mixture was heated at 320° C. for 30 minutes with stirring (the shell coating step).

Thereafter, the operation of the above (the washing step) and (the shell coating step) was repeated three times to finally obtain the reaction solution (ZnSe/ZnS) as a target product, and the reaction solution was cooled to room temperature.

The obtained reaction solution was measured with a fluorescence spectrometer. As a result, the optical characteristics were obtained in which the fluorescence wavelength was about 443 nm and the fluorescence half-value width was about 15 nm.

Ethanol was added to the obtained reaction solution to generate a precipitate, the precipitate was recovered by centrifugation, and hexane was added to and dispersed in the precipitate.

Hexane-dispersed ZnSe/ZnSeS/ZnS was measured with a quantum efficiency measurement system. As a result, the fluorescence quantum yield was about 60%. In addition, as a result of measuring the fluorescence lifetime, it was 14 ns.

In addition, the quantum dots obtained in Comparative Example 1 were applied to manufacture a light-emitting element having the following stacked structure.

ITO/PEDOT: PSS/PVK/QD Layer/ZnO/Al

The present element was evaluated using an LED measuring device, and as a result, the maximum value of the external quantum efficiency (EQE) was 4.0%.

Hereinafter, Example 1 and Comparative Example 1 will be compared. Table 1 is a table showing the measurement results of Example 1 and Comparative Example 1.

TABLE 1

| | | COMPARATIVE |
|---|---|---|
| | EXAMPLE 1 | EXAMPLE 1 |
| FLUORESCENCE WAVELENGTH | 441.5 | 443.0 |
| (nm) | | |
| HALF-VALUE WIDTH (nm) | 15.0 | 15.0 |
| PLQY (SOLUTION) (%) | 96 | 60 |
| FLUORESCENCE LIFETIME 1/e | 16 | 14 |
| (SOLUTION) (ns) | | |
| SHELL THICKNESS (nm) | 2.0 | 2.0 |
| EQE (%) | 18.6 | 4.0 |

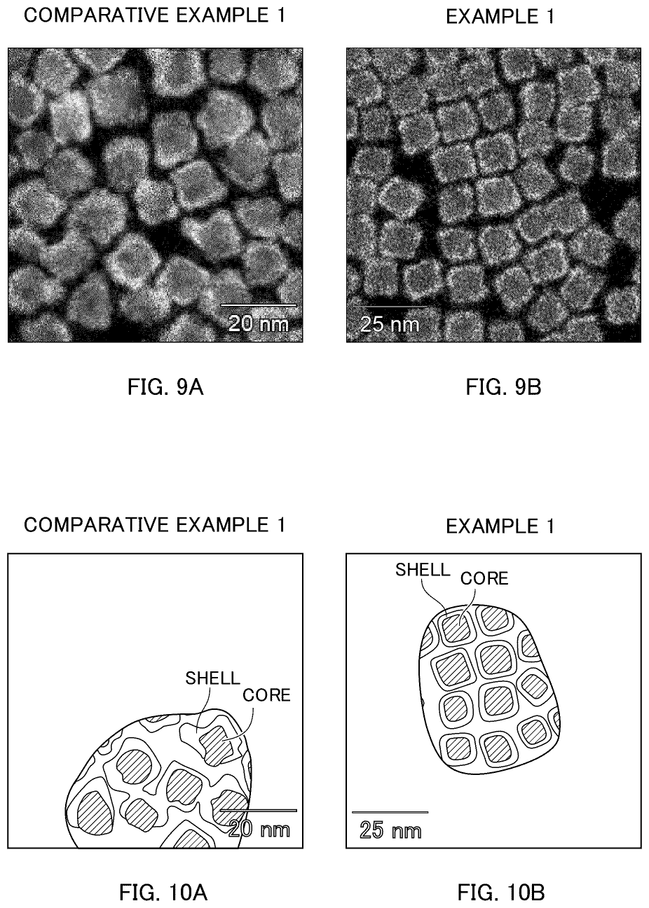

It was found that the EQE in Comparative Example 1 was lower than that in Example 1. FIG. 9A is the photograph of the analysis result of TEM-EDX in Comparative Example 1, and FIG. 9B is the photograph of the analysis result of TEM-EDX in Example 1. FIG. 10A is the partial schematic view of FIG. 9A, and FIG. 10B is the partial schematic view of FIG. 9B.

As shown in FIGS. 9A and 9B, the photographs of the analysis results of TEM-EDX are shown in three colors (red, blue, and green), and it was found that a central portion is substantially purple with mainly red and blue mixed, and an outer portion is substantially yellow with mainly red and green mixed. Since red indicates Zn, blue indicates Se, and green indicates S, it was found that mainly Zn and Se exist in the central portion, and mainly Zn and S exist outside. Accordingly, from the photographs of the analysis results of TEM-EDX shown in FIGS. 9A and 9B, it can be estimated that the core is ZnSe and the shell is ZnS. Then, the shell thickness can be estimated by measuring the thickness of the substantially yellow portion from the photograph of the analysis result of TEM-EDX.

From FIGS. 9A and 10A, in Comparative Example 1, the shell covering the periphery of the core was not substantially constant in thickness, and there were some portions where the shell was interrupted or locally grown. Accordingly, the particle shape of Comparative Example 1 was deteriorated, the Forster resonance energy transfer (FRET) easily occurred, and the EQE decreased. In addition, in Comparative Example 1, a QY higher than that in Example 1 was not obtained.

On the other hand, in Example 1, as shown in FIGS. 9B and 10B, the shell cleanly covered the entire circumference of the core, the shell had the substantially constant thickness, and the particle shape of the quantum dot was the substantially rectangular shape. As described above, the particle shape of Example 1 was better than that of Comparative Example 1, and in addition, a sufficiently higher QY than that of Comparative Example 1 could be obtained. As a result, in Example 1, the EQE sufficiently higher than that in Comparative Example 1 could be obtained.

### INDUSTRIAL APPLICABILITY

According to the present invention, the quantum dots that emit the blue fluorescence can be stably obtained. Then, by applying the quantum dot of the present invention to the LED, the backlight device, the display device, or the like, excellent light emission characteristics can be obtained in each device.

This application is based on Japanese Patent Application No. 2021-030560 filed on Feb. 26, 2021. All the contents are included here.

1. A method for manufacturing a quantum dot, comprising:
generating a core; and
coating a surface of the core with a shell, wherein
in the coating the shell, an acidic compound and a zinc halide compound are blended into a shell raw material.

2. The method for manufacturing a quantum dot according to claim 1, wherein the surface of the core containing at least Zn and Se is coated with ZnS.

3. The method for manufacturing a quantum dot according to claim 1, wherein
the coating the shell is divided into at least a first half and a second half, and
the shell is coated a plurality of times, in the first half, using a shell raw material in which the acidic compound is blended and the zinc halide compound is not blended, and in the second half, using a shell raw material in which both the acidic compound and the zinc halide compound are blended.

4. The method for manufacturing a quantum dot according to claim 1, wherein at least one of hydrogen chloride, hydrogen bromide, or trifluoroacetic acid is used as the acidic compound.

5. The method for manufacturing a quantum dot according to claim 1, wherein at least one of zinc chloride and zinc bromide is used as the zinc halide compound.

6. A quantum dot comprising: a core and a shell covering a surface of the core, wherein
a halogen element is contained, and
an external quantum efficiency is 7% or more.

7. A quantum dot comprising: a core and a shell covering a surface of the core, wherein
a halogen element is contained, and
a fluorescence quantum yield is 70% or more.

8. A quantum dot comprising: a core and a shell covering a surface of the core, wherein
the shell is formed by blending an acidic compound and a zinc halide compound in a shell raw material.

9. The quantum dot according to claim 6, wherein the core contains at least Zn and Se, and the shell is made of ZnS.
